(19) United States
(12) Patent Application Publication
(10) Pub. No.: US 2014/0022853 A1
(43) Pub. Date: Jan. 23, 2014

(54) MEMORY DEVICE, MEMORY SYSTEM, AND METHOD OF CONTROLLING READ VOLTAGE OF THE MEMORY DEVICE

(71) Applicant: SAMSUNG ELECTRONICS CO., LTD., Suwon-si (KR)

(72) Inventors: MYUNG-HOON CHOI, SUWON-SI (KR); JAE-YONG JEONG, YONGIN-SI (KR); KI-TAE PARK, SEONGNAM-SI (KR); HYUN-JUN YOON, SEONGNAM-SI (KR)

(21) Appl. No.: 13/908,005

(22) Filed: Jun. 3, 2013

(30) Foreign Application Priority Data
Jul. 23, 2012 (KR) 10-2012-0080246

(51) Int. Cl. G11C 16/24

(52) U.S. Cl. CPC G11C 16/24
USPC 365/189.05

(57) ABSTRACT

A memory device includes a memory cell array and a page buffer unit. The memory cell array includes multiple memory cells. The page buffer unit performs a logic operation on data sequentially read from the memory cells at different voltage levels, based on the read data and a read direction of applying the different voltage levels.

### CROSS-REFERENCE TO RELATED APPLICATION

A claim for priority under 35 U.S.C. §119 is made to Korean Patent Application No. 10-2012-0080246, filed on Jul. 23, 2012, in the Korean Intellectual Property Office, the entire contents of which are hereby incorporated by reference.

### BACKGROUND

Embodiments of the inventive concept relate to a memory device, and more particularly, to a memory device, a memory system, and a method of controlling a read voltage of the memory device.

Memory devices are used to store data, and may be classified as volatile memory devices or non-volatile memory devices. In order to improve reliability of a memory device by accurately reading data stored in the memory device, a voltage level of a read voltage has to be determined accurately.

Embodiments of the inventive concept provide a memory device and a memory system capable of reducing operation time taken to determine a read voltage and preventing operation errors due to read errors.

According to an aspect of the inventive concept, there is provided a memory device including a memory cell array and a page buffer unit. The memory cell array includes multiple memory cells. The page buffer unit performs a logic operation on data sequentially read from the memory cells at different voltage levels, based on the read data and a read direction of applying the different voltage levels.

The memory cells may be disposed in regions where multiple wordlines and multiple bitlines cross each other. The page buffer unit may include multiple page buffers connected to the multiple bitlines, respectively.

Each of the page buffers may determine whether to precharge a corresponding bitline based on the data sequentially read at the different voltage levels from a memory cell connected to the corresponding bitline from among the multiple memory cells and the read direction of applying the different voltage levels.

When the read direction is a direction of applying increasing voltage levels, each of the page buffers may continuously precharge the corresponding bitline when currently read data has a first logic level, and stop precharging the corresponding bitline when the currently read data has a second logic level, where the first logic level corresponds to the memory cell being turned off, and the second logic level corresponds to the memory cell being turned on.

When the read direction is a direction of applying decreasing voltage levels, each of the page buffers may continuously precharge the corresponding bitline when currently read data has a second logic level, and stop precharging the corresponding bitline when the currently read data has a first logic level, where the first logic level corresponds to the memory cell being turned off, and the second logic level corresponds to the memory cell being turned on.

Each of the page buffers may perform an XOR operation on the read data. Also, each of the page buffers may include a bitline connection unit for connecting a corresponding bitline to a sensing node, a precharge unit for selectively precharging the sensing node based on a voltage of the sensing node, and a logic operation performing unit connected to the sensing node for performing the logic operation on the data sequentially read at the different voltage levels.

When the read direction is a direction of applying increasing voltage levels, the precharge unit may continuously precharge the sensing node when currently read data has a first logic level, and stop precharging the sensing node when the currently read data has a second logic level, where the first logic level corresponds to a case when the memory cell is turned off, and the second logic level corresponds to a case when the memory cell is turned on. When the read direction is a direction of applying decreasing voltage levels, the precharge unit may continuously precharge the sensing node when the currently read data has a second logic level, and stop precharging the sensing node when the currently read data has the first logic level, where the first logic level corresponds to a case when the memory cell is turned off, and the second logic level corresponds to a case when the memory cell is turned on.

The precharge unit may precharge the sensing node in an initial state. Also, the precharge unit may include a precharge control unit for determining whether to precharge the sensing node, based on the voltage of the sensing node, and generating a precharge control signal; and a precharge performing unit for precharging the sensing node based on the precharge control signal.

The precharge control unit may include a sensing latch connection unit for transmitting the voltage of the sensing node to a latch input node; a sensing latch for latching and transmitting a voltage of the latch input node to a latch output node, and providing a voltage of the latch output node to the precharge performing unit as the precharge control signal; and a sensing latch control unit for controlling the sensing latch based on a plurality of control signals.

The memory device may further include a counter for counting a number of memory cells in each of multiple sections defined by the different voltage levels based on results of the logic operation.

The memory device may further include a read voltage control unit for counting a number of memory cells in each section of multiple sections defined by the different voltage levels, based on results of the logic operation, and for controlling a read voltage of the memory cells based on a result of the counting.

According to another aspect of the inventive concept, there is provided a memory system including a memory device and a memory controller for controlling the memory device. The memory device includes a memory cell array having multiple memory cells and a page buffer unit for performing a logic operation on data sequentially read from the memory cells at different voltage levels, based on the read data and a read direction of applying the different voltage levels.

The memory controller may include a read voltage control unit for counting a number of memory cells in each section of multiple sections defined by the different voltage levels, based on results of the logic operation, and for controlling a read voltage of the memory cells based on a result of the counting.

According to another aspect of the inventive concept, there is provided a method of controlling a read voltage for reading data stored in a memory cell array comprising multiple memory cells. The method includes reading data from the memory cells by sequentially applying different voltage levels to each of the memory cells; temporarily storing the read data in multiple page buffers corresponding to multiple bitlines connected to the memory cells; and determining whether to precharge the bitlines based on the read data temporarily stored in the corresponding page buffers and a read direction of applying the different voltage levels.

The method may further include performing a logic operation in each of the page buffers on the data read at adjacent voltage levels, and determining an optimum voltage level of a read voltage of the memory cells based on results of the logic operation.

Determining the optimum voltage level of the read voltage may include counting a number of memory cells in each of multiple sections defined by the voltage levels based on results of the logic operation; detecting a valley between distributions of memory cells in two adjacent states, based on the counted numbers of memory cells; and determining a voltage level corresponding to the detected valley as the optimum voltage level of the read voltage. The logic operation comprises an XOR operation.

### BRIEF DESCRIPTION OF THE DRAWINGS

Exemplary embodiments of the inventive concept will be more clearly understood from the following detailed description taken in conjunction with the accompanying drawings in which:

FIG. 1 is a block diagram of a memory system, according to an embodiment of the inventive concept;

FIG. 2 is a detailed block diagram of a memory device included in the memory system illustrated in FIG. 1 according to an embodiment of the inventive concept;

FIG. 3 is a diagram showing an example of a memory cell array included in the memory device illustrated in FIG. 2, according to an embodiment of the inventive concept;

FIG. 4 is a circuit diagram of an example of a memory block included in the memory cell array illustrated in FIG. 3, according to an embodiment of the inventive concept;

FIG. 5 is a cross-sectional view of an example of a memory cell included in the memory block illustrated in FIG. 4, according to an embodiment of the inventive concept;

FIG. 6A is a graph showing distributions of memory cells versus threshold voltages of the memory device when the memory cell illustrated in FIG. 5 is a 2-bit multi-level cell;

FIG. 6B is a graph showing a case when the threshold voltages of the memory cells illustrated in FIG. 6A have varied;

FIG. 7 is a graph showing two adjacent distributions shown in FIG. 6B;

FIG. 8 is a diagram for describing an operation of reading data of two adjacent voltage levels shown in FIG. 7, according to an embodiment of the inventive concept, according to an embodiment of the inventive concept;

FIG. 9 is a diagram for describing a read operation of a memory cell having a threshold voltage between second and third voltage levels shown in FIG. 7;

FIG. 10 is a diagram for describing an example of a method of removing an operation error shown in FIG. 9;

FIG. 11 is a detailed block diagram of the memory device illustrated in FIG. 1, according to an embodiment of the inventive concept;

FIG. 12 is a detailed block diagram of a page buffer illustrated in FIG. 11, according to an embodiment of the inventive concept;

FIG. 13 is a detailed block diagram of precharge control unit in the page buffer illustrated in FIG. 12, according to an embodiment of the inventive concept;

FIG. 14 is a circuit diagram of the page buffer illustrated in FIG. 13, according to an embodiment of the inventive concept;

FIG. 15A is a table showing an operation result of the page buffer illustrated in FIGS. 11 to 14, when a read direction is a direction of applying increasing voltage levels, according to an embodiment of the inventive concept;

FIG. 15B is a table showing an operation result of the page buffer illustrated in FIGS. 11 to 14, when a read direction is a direction of applying decreasing voltage levels, according to an embodiment of the inventive concept;

FIG. 16 is a graph showing a result of counting performed by a read voltage control unit illustrated in FIG. 1, according to an embodiment of the inventive concept;

FIG. 17 is a block diagram of a memory system, according to another embodiment of the inventive concept;

FIG. 18 is a detailed block diagram of a memory device included in the memory system illustrated in FIG. 17, according to an embodiment of the inventive concept;

FIG. 19 is a flowchart of a method of controlling a read voltage of a memory device, according to an embodiment of the inventive concept;

FIG. 20 is a detailed flowchart of a step of determining whether to perform precharge in the method illustrated in FIG. 19, according to an embodiment of the inventive concept;

FIG. 21 is a flowchart of a method of controlling a read voltage of a memory device, according to another embodiment of the inventive concept;

FIG. 22 is a detailed flowchart of a step of controlling the read voltage in the method illustrated in FIG. 21, according to an embodiment of the inventive concept; and

FIG. 23 is a block diagram of a computing system including a memory system, according to an embodiment of the inventive concept.

### DETAILED DESCRIPTION OF THE EMBODIMENTS

The inventive concept will now be described more fully with reference to the accompanying drawings, in which exemplary embodiments of the inventive concept are shown. The inventive concept may, however, be embodied in many different forms and should not be construed as being limited to the embodiments set forth herein; rather, these embodiments are provided so that this disclosure will be thorough and complete, and will fully convey the concept of the inventive concept to one of ordinary skill in the art. It should be understood, however, that there is no intent to limit exemplary embodiments of the inventive concept to the particular forms disclosed, but conversely, exemplary embodiments of the inventive concept are to cover all modifications, equivalents, and alternatives falling within the spirit and scope of the inventive concept. In the drawings, like reference numerals denote like elements and the sizes or thicknesses of elements may be exaggerated for clarity of explanation.

The terminology used herein is for the purpose of describing particular embodiments and is not intended to limit the inventive concept. As used herein, the singular forms “a”, “an”, and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the inventive concept.

Unless defined differently, all terms used in the description including technical and scientific terms have the same meaning as generally understood by one of ordinary skill in the art. Terms as defined in a commonly used dictionary should be construed as having the same meaning as in an associated technical context, and unless defined in the description, the terms are not ideally or excessively construed as having formal meaning.

As used herein, the term “and/or” includes any and all combinations of one or more of the associated listed items.

FIG. 1 is a block diagram of a memory system 1 according to an embodiment of the inventive concept.

Referring to FIG. 1, the memory system 1 includes a memory controller 10A and a memory device 20A. The memory controller 10A includes an error correction code (ECC) processing unit 11 and a read voltage control unit 12. The memory device 20A includes a memory cell array 21 and a page buffer unit 22. The elements included in the memory controller 10A and the memory device 20A will now be described in detail.

The memory controller 10A performs an operation of controlling the memory device 20A. In more detail, the memory controller 10A controls program (or record), read, and erase operations of the memory device 20A by supplying address signals ADDR, command signals CMD, and control signals CTRL to the memory device 20A.

The memory cell array 21 includes a plurality of memory cells (not shown) disposed in regions where a plurality of wordlines (not shown) and a plurality of bitlines (not shown) cross each other. In one embodiment, the memory cells may be flash memory cells, and the memory cell array 21 may be a NAND flash memory cell array or a NOR flash memory cell array. Hereinafter, it is assumed that the memory cells are flash memory cells. However, the memory cells are not limited thereto and may be memory cells of a resistive memory such as resistive random access memory (RRAM), phase-change random access memory (PRAM), or magnetic random access memory (MRAM), for example.

The page buffer unit 22 temporarily stores data to be recorded onto or data read from the memory cell array 21. In the current embodiment, the page buffer unit 22 may include a plurality of page buffers (not shown), where the number of page buffers corresponds to the number of bit lines. That is, the number of page buffers may be the same as the number of bit lines.

In more detail, when a read operation of the memory device 20A is performed, each of the page buffers performs a logic operation on data sequentially read at different voltage levels from a corresponding memory cell from among the memory cells, based on a read direction of applying the different voltage levels. In the current embodiment, each of the page buffers performs an XOR operation on first and second data read at two adjacent voltage levels from among the different voltage levels.

The ECC processing unit 11 checks whether an error, i.e., a read error, exists in the data read from the memory device 20A and corrects the read error. For example, the ECC processing unit 11 may compare a parity generated and stored when the data is programmed, with a parity generated when the data is read, may detect an error bit of the data, and may perform an XOR operation on the detected error bit so as to correct the read error. As such, even when data is read at an initial read voltage from a memory cell included in the memory cell array 21 and then the ECC processing unit 11 corrects a read error, when a read failure occurs, the read voltage control unit 12 may be activated to perform an operation of determining a read voltage.

The read voltage control unit 12 receives a result of a logic operation from the page buffer unit 22, and controls a read voltage of memory cells based on the received result of the logic operation. For example, the read voltage control unit 12 may count the number of memory cells in each section of multiple sections defined by different voltage levels, based on the received result of the logic operation, and determine an optimum voltage level of the read voltage based on results of the counting. In more detail, the read voltage control unit 12 may determine the read voltage as a voltage level corresponding to where the number of memory cells in the sections decreases and then increases.

Since the read voltage control unit 12 is included, even when threshold voltages of the memory cells have varied due to an external stimulus and/or wearing, the memory controller 10A is able to control a voltage level of the read voltage based on the varied threshold voltages. As such, a raw bit error rate (RBER) may be improved.

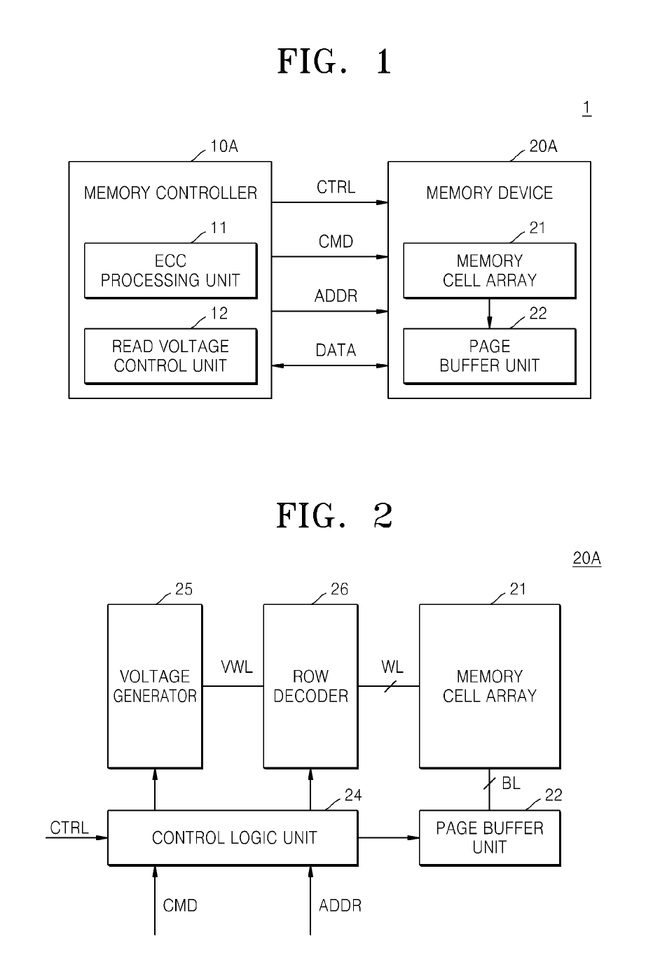

FIG. 2 is a detailed block diagram of the memory device 20A included in the memory system 1 illustrated in FIG. 1, according to an embodiment of the inventive concept.

Referring to FIG. 2, the memory device 20A includes the memory cell array 21, the page buffer unit 22, a control logic unit 24, a voltage generator 25, and a row decoder 26.

The control logic unit 24 outputs various control signals for writing or reading data into or from the memory cell array 21 based on the command signals CMD, the address signals ADDR, and the control signals CTRL received from the memory controller 10A. In this case, the various control signals output from the control logic unit 24 may be transmitted to the voltage generator 25, the row decoder 26, and the page buffer unit 22.

The voltage generator 25 generates driving voltages VWL for driving a plurality of wordlines WL based on the control signals received from the control logic unit 24. For example, the driving voltages VWL may be write voltages (or program voltages), read voltages, erase voltages, or pass voltages.

The row decoder 26 activates some of the wordlines WL based on a row address. For example, in a read operation, the row decoder 26 may apply a read voltage to a selected wordline WL and may apply a pass voltage to an unselected wordline WL. In a write operation, the row decoder 26 may apply a write voltage to the selected wordline WL and may apply a pass voltage to the unselected wordline WL.

The page buffer unit 22 is connected to the memory cell array 21 via a plurality of bit lines BL. For example, in the read operation, the page buffer unit 22 may function as a sense amplifier and output data stored in the memory cell array 21. In the write operation, the page buffer unit 22 may function as a write driver and input data to be stored, to the memory cell array 21. In another embodiment, the page buffer unit 22 may be connected to a data input/output (I/O) circuit (not shown) via a plurality of data lines.

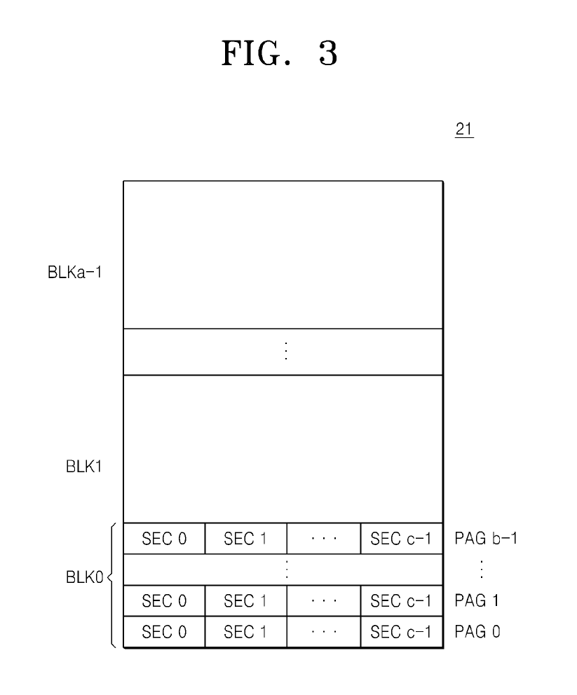

FIG. 3 is a diagram showing an example of the memory cell array 21 included in the memory device 20A illustrated in FIG. 2, according to an embodiment of the inventive concept.

Referring to FIG. 3, the memory cell array 21 may be a flash memory cell array, for example. In this case, the memory cell array 21 may include a blocks BLK0 to BLKa−1 (a being an integer equal to or greater than 2), each of the a blocks BLK0 to BLKa−1 may include b pages PAG0 to PAGb−1 (b being an integer equal to or greater than 2), and each of the b pages PAG0 to PAGb−1 may include c sectors SEC0 to SECc−1 (c being an integer equal to or greater than 2). Although, for convenience of illustration, only the block BLK0 includes the b pages PAG0 to PAGb−1 and the c sectors SEC0 to SECc−1 in FIG. 3, the other blocks BLK1 to BLKa−1 may have the same structure as that of the block BLK0.

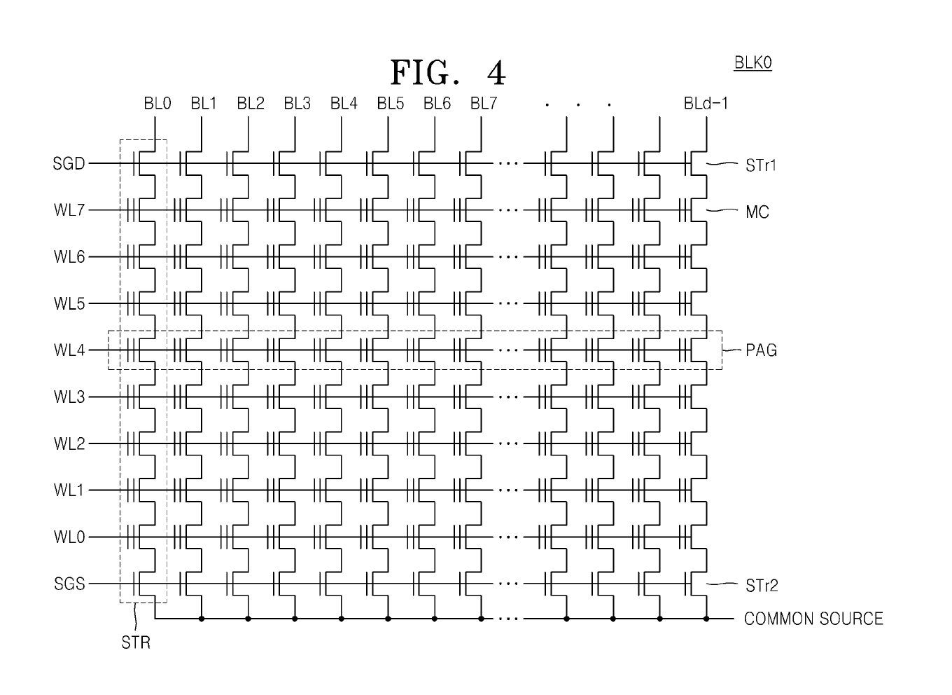

FIG. 4 is a circuit diagram of an example of the memory block BLK0 included in the memory cell array 21 illustrated in FIG. 3, according to an embodiment of the inventive concept.

Referring to FIG. 4, the memory cell array 21 may be a memory cell array of a NAND flash memory. In this case, each of the a blocks BLK0 to BLKa−1 illustrated in FIG. 3 may be implemented as illustrated in FIG. 4. Referring to FIG. 4, each of the a blocks BLK0 to BLKa−1 may include d strings STR (d being an integer equal to or greater than 2) in which eight memory cells MC are connected in series in directions of bitlines BL0 to BLd−1. Each of the d strings STR may include a drain selection transistor Str1 and a source selection transistor Str2 connected to two ends of the eight memory cells MC connected in series.

A NAND flash memory device having the structure of FIG. 4 may perform an erase operation in units of blocks and may perform a program operation in units of pages PAG corresponding to wordlines WL0 to WL7. FIG. 4 illustrates an example when eight pages PAG corresponding to eight wordlines WL0 to WL7 are included in one block. However, the a blocks BLK0 to BLKa−1 of the memory cell array 21 illustrated in FIG. 3 may include memory cells and pages of which numbers are different from the numbers of the memory cells MC and the pages PAG illustrated in FIG. 4. Also, the memory device 20A illustrated in FIGS. 1 and 2 may include a plurality of memory cell arrays for performing the same operation as and have the same structure as those of the memory cell array 21 described above.

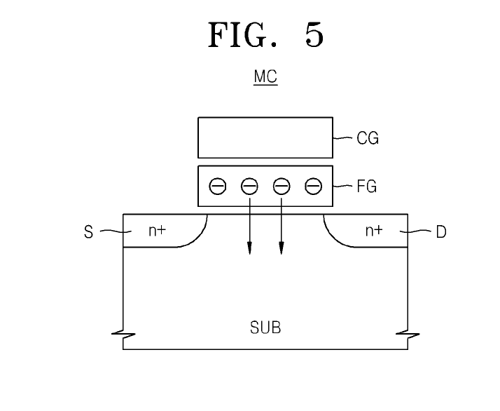

FIG. 5 is a cross-sectional view of an example of the illustrative memory cell MC included in the memory block BLK0 illustrated in FIG. 4, according to an embodiment of the inventive concept.

Referring to FIG. 5, a source S and a drain D may be formed on a substrate SUB, and a channel may be formed between the source S and the drain D. A floating gate FG may be formed above the channel, and an insulating layer, e.g., a tunneling insulating layer, may be formed between the channel and the floating gate FG. A control gate CG may be formed above the floating gate FG, and an insulating layer, e.g., a blocking insulating layer, may be formed between the floating gate FG and the control gate CG. Voltages required for program, erase, and read operations of the memory cell MC may be applied to the substrate SUB, the source S, the drain D, and the control gate CG.

In a flash memory device, data stored in the memory cell MC may be read by distinguishing a threshold voltage Vth of the memory cell MC. In this case, the threshold voltage Vth of the memory cell MC may be determined based on the amount of electrons stored in the floating gate FG. In more detail, if the amount of electrons stored in the floating gate FG is increased, the threshold voltage Vth of the memory cell MC may also be increased.

The electrons stored in the floating gate FG of the memory cell MC may leak, for various reasons, in a direction of arrows shown in FIG. 5, and thus the threshold voltage Vth of the memory cell MC may vary. For example, the electrons stored in the floating gate FG may leak due to wearing of the memory cell MC. In more detail, when an access operation, e.g., a program, erase, or read operation, is repeatedly performed on the memory cell MC, the insulating layer between the channel and the floating gate FG may deteriorate, and thus the electrons stored in the floating gate FG may leak. As another example, the electrons stored in the floating gate FG may leak due to a high-temperature stress or a difference in temperatures when the program/read operation is performed.

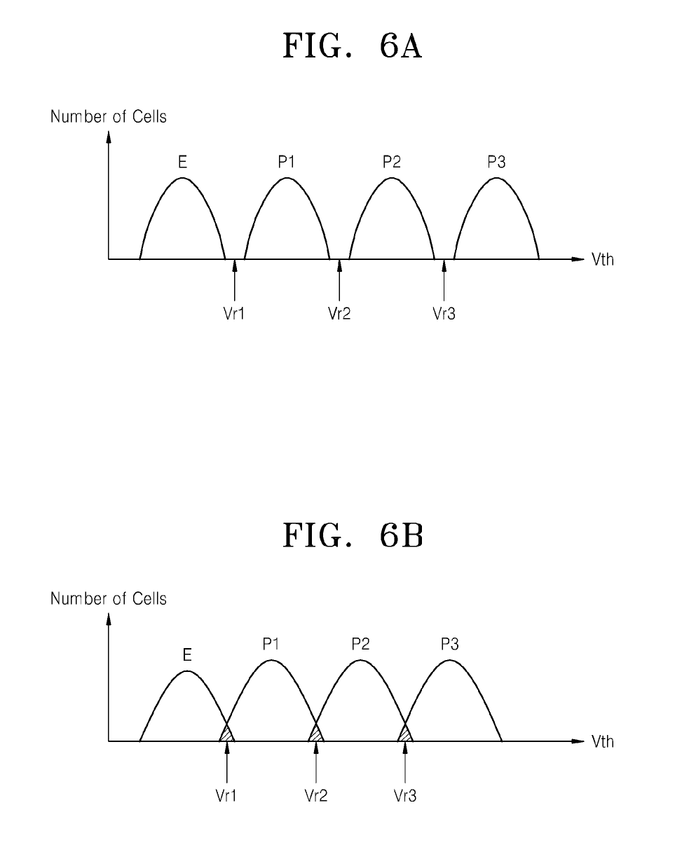

FIG. 6A is a graph showing distributions of memory cells versus threshold voltages Vth of the memory device 20A when the memory cell MC illustrated in FIG. 5 is a 2-bit multi-level cell.

Referring to 6A, the horizontal axis represents the threshold voltages Vth, and the vertical axis represents the number of memory cells. When the memory cell MC is a 2-bit multi-level cell programmed with two bits, the memory cell MC may be in one of an erased state E, a first programmed state P1, a second programmed state P2, and a third programmed state P3. Since a distance between distributions of the threshold voltages Vth in a multi-level cell is smaller than that in a single level cell, in the multi-level cell, a serious problem may occur due to small variations in the threshold voltages Vth.

A first read voltage Vr1 has a voltage level between a distribution of the memory cells MC in the erased state E and a distribution of the memory cells MC in the first programmed state P1. A second read voltage Vr2 has a voltage level between a distribution of the memory cells MC in the first programmed state P1 and a distribution of the memory cells MC in the second programmed state P2. A third read voltage Vr3 has a voltage level between a distribution of the memory cells MC in the second programmed state P2 and a distribution of the memory cells MC in the third programmed state P3.

For example, when the first read voltage Vr1 is applied to the control gate CG of the memory cell MC, the memory cell MC in the erased state E is turned on, while the memory cell MC in the first programmed state P1 is turned off. A current flows through the memory cell MC when the memory cell MC is turned on, and does not flow through the memory cell MC when the memory cell MC is turned off. Accordingly, data stored in the memory cell MC may be distinguished depending on whether the memory cell MC is turned on.

In one embodiment, when the first read voltage Vr1 is applied, it may be distinguished that data “1” is stored if the memory cell MC is turned on, and that data “0” is stored if the memory cell MC is turned off. However, logic levels of data are not limited thereto. In another embodiment, when the first read voltage Vr1 is applied, it may be distinguished that data “0” is stored if the memory cell MC is turned on, and that data “1′” is stored if the memory cell MC is turned off. The logic levels of data may be variously assigned according to an embodiment.

FIG. 6B is a graph showing a case when the threshold voltages Vth of the memory cells MC illustrated in FIG. 6A have varied.

Referring to FIG. 6B, the memory cells MC programmed to the erased state E and the first through third programmed states P1 to P3 may have distributions that have varied as illustrated in FIG. 6B, due to external stimulus and/or wearing. In FIG. 6B, the memory cells MC in slashed portions may have read errors, and thus the reliability of the memory device 20A may be lowered.

For example, when a read operation is performed on the memory device 20A by using the first read voltage Vr1, although the memory cells MC in slashed portions are programmed to the first programmed state P1, the memory cells MC may be determined to be in the erased state E due to decreases in the threshold voltages Vth. As such, an error may occur in the read operation, and the reliability of the memory device 20A may be lowered.

When data is read from the memory device 20A, a RBER varies depending on a voltage level of a read voltage, and an optimum voltage level of the read voltage may be determined depending on the shape of the distributions of the memory cells MC. Accordingly, if the distributions of the memory cells MC vary, the optimum voltage level of the read voltage required to read data from the memory device 20A may also vary. Thus, the optimum voltage level of the read voltage should be determined by varying the voltage level of the read voltage based on variations in the distributions. In this case, in order to efficiently determine the optimum voltage level of the read voltage, an operation time should be reduced by performing a simple operation based on a small amount of test data.

A case when the memory cell MC is a 2-bit multi-level cell is described above in relation to FIGS. 6A and 6B. However, the memory cell MC illustrated in FIG. 5 is not limited thereto and may be a single-level cell or 3-or-more-bit multi-level cell. Also, the memory device 20A illustrated in FIGS. 1 and 2 may include the memory cells MC programmed with different numbers of bits.

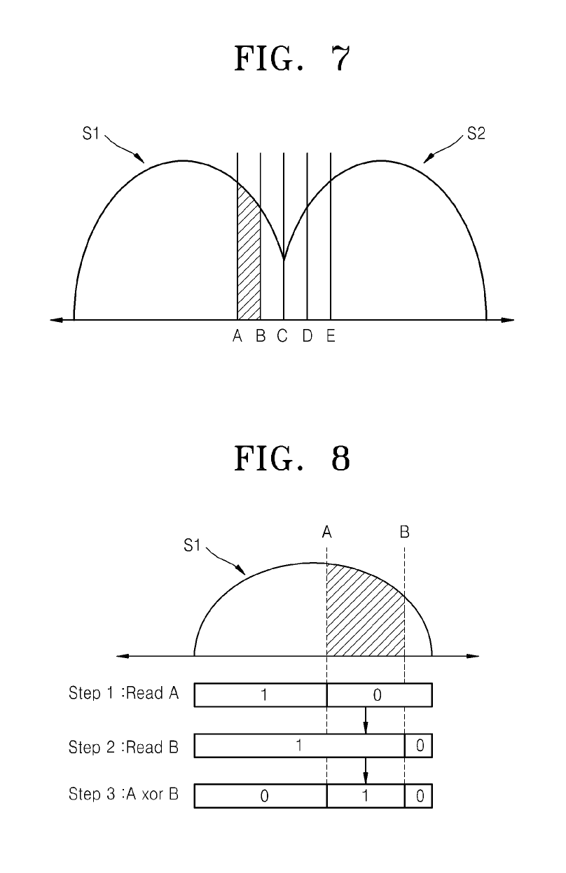

FIG. 7 is a graph showing two adjacent distributions S1 and S2 shown in FIG. 6B.

Referring to FIGS. 1 and 7, the memory controller 10A may read data from the memory cells MC at each of first through fifth voltage levels A to E corresponding to an overlapping region of the two adjacent distributions 51 and S2 of the memory cells MC included in the memory device 20A. In this case, by counting the number of the memory cells MC included in each of multiple sections defined by the first through fifth voltage levels A to E, an optimum voltage level of a read voltage between the two adjacent distributions S1 and S2 may be determined. The above-described method of determining a read voltage between two adjacent distributions is referred to as “minimal error search (MES).”

FIG. 8 is a diagram for describing an operation of reading data at two adjacent voltage levels, e.g., the first and second voltage levels A and B, shown in FIG. 7.

Referring to FIGS. 1 and 8, in step 1, the memory controller 10A reads first data D1 from the memory cells MC at the first voltage level A. In this case, “1” is read from the memory cells MC having threshold voltages Vth lower than the first voltage level A, and “0” is read from the memory cells MC having threshold voltages Vth higher than the first voltage level A. The first data D1 read in step 1 may be temporarily stored in the page buffer unit 22.

In step 2, the memory controller 10A reads second data D2 from the memory cells MC at the second voltage level B. In this case, “1” is read from the memory cells MC having threshold voltages Vth lower than the second voltage level B, and “0” is read from the memory cells MC having threshold voltages Vth higher than the second voltage level B. The second data D2 read in step 2 may be temporarily stored in the page buffer unit 22.

In step 3, the page buffer unit 22 performs a logic operation on the first data D1 read at the first voltage level A and the second data D2 read at the second voltage level B.

In one embodiment, the page buffer unit 22 may perform an XOR operation on the first and second data D1 and D2, for example.

A result of the XOR operation performed on the first and second data D1 and D2 with respect to the memory cells MC having threshold voltages Vth lower than the first voltage level A is “0.” A result of the XOR operation performed on the first and second data D1 and D2 with respect to the memory cells MC having threshold voltages Vth between the first and second voltage levels A and B is “1.” A result of the XOR operation performed on the first and second data D1 and D2 with respect to the memory cells MC having threshold voltages Vth higher than the second voltage level B is “0.”

Accordingly, it may be determined whether the memory cells MC are included in the section defined by the first and second voltage levels A and B, based on the results of the XOR operation on the first and second data D1 and D2. That is, the memory cells MC included in a section where the result of the XOR operation is “1” are determined to be in the section defined by the first and second voltage levels A and B. The memory cells MC included in this section may be counted. By using the above-described method of counting the number of memory cells in each of the multiple sections defined by the voltage levels, a valley between two adjacent distributions may be detected and a voltage level corresponding to the valley may be determined as an optimum voltage level of a read voltage.

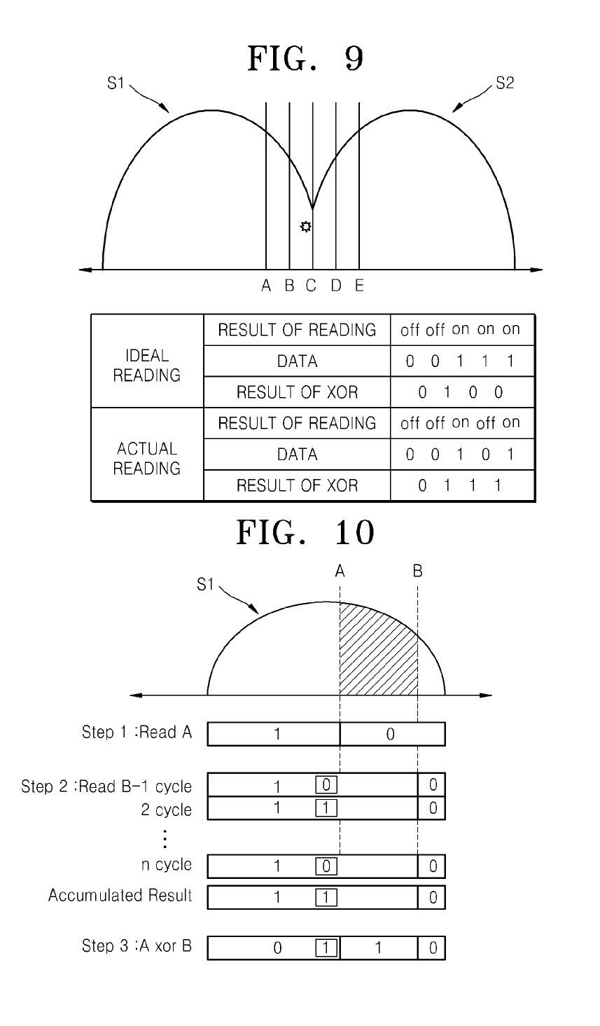

FIG. 9 is a diagram for describing an illustrative read operation of a memory cell MC having a threshold voltage Vth between the second and third voltage levels B and C shown in FIG. 7.

Initially, an ideal read operation will be described referring to FIG. 9. When data is read from the memory cell MC at the first and second voltage levels A and B, since the first and second voltage levels A and B are lower than the threshold voltage Vth of the memory cell MC, it is determined that the memory cell MC is in an “off” state. Accordingly, it is determined that the first data D1 read at the first voltage level A and the second data D2 read at the second voltage level B are “0.” When data is read from the memory cell MC at the third through fifth voltage levels C to E, since the third through fifth voltage levels C to E are higher than the threshold voltage Vth of the memory cell MC, it is determined that the memory cell MC is in an “on” state. Accordingly, it is determined that third data D3 read at the third voltage level C, fourth data D4 read at the fourth voltage level D, and fifth data D5 read at the fifth voltage level E are “1.”

The page buffer unit 22 may perform a logic operation, e.g., an XOR operation, on data read at two adjacent voltage levels from among the first through fifth voltage levels A to E. In this case, a result of the XOR operation performed on the first and second data D1 and D2 is “0,” a result of the XOR operation performed on the second and third data D2 and D3 is “1,” a result of the XOR operation performed on the third and fourth data D3 and D4 is “0,” and a result of the XOR operation performed on the fourth and fifth data D4 and D5 is “0.” Based on these results, the read voltage control unit 12 is able to determine that the memory cell MC exists between the second and third voltage levels B and C.

However, in an actual read operation, a read error may occur due to unstable operation of the memory cell MC, power noise, an unstable analog level, and the like. For example, when data is read from the memory cell MC at the fourth voltage level D, although the fourth voltage level D is higher than the threshold voltage Vth of the memory cell MC, it may be inaccurately determined that the memory cell MC is in an “off” state and that the fourth data D4 read at the fourth voltage level D is “0.” In this case, a result of an XOR operation performed on the third and fourth data D3 and D4 is “1,” and a result of the XOR operation performed on the fourth and fifth data D4 and D5 is also “1.”

The above-described read error of the memory cell MC causes an operation error of the read data. When the operation error occurs, an optimum voltage level of a read voltage for reading the memory cell MC may not be accurately determined and thus the reliability of a read operation of the memory device 20A may be greatly reduced.

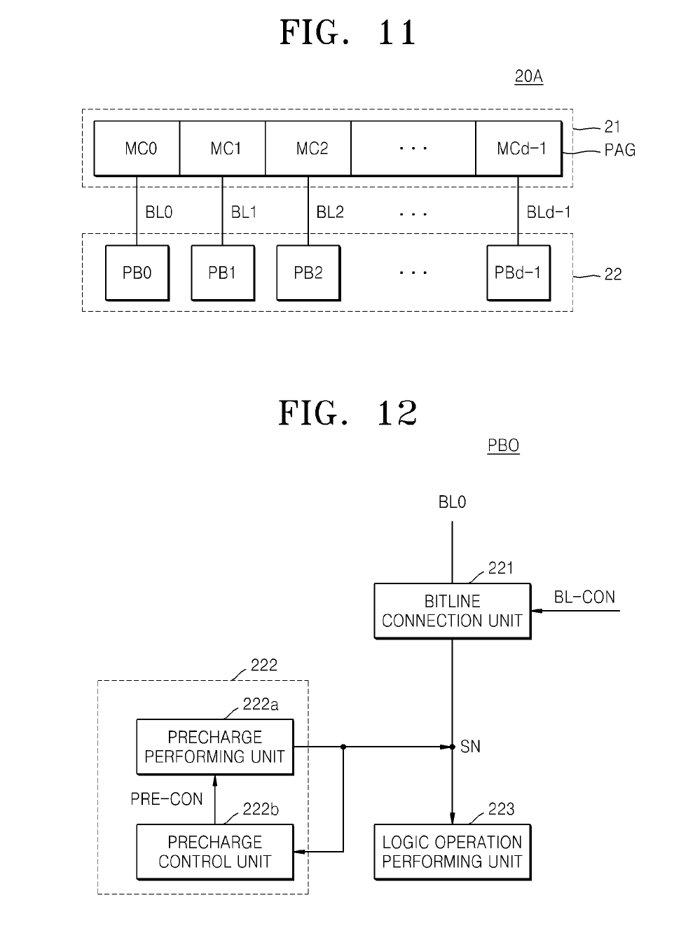

FIG. 10 is a diagram for describing an example of a method of removing an operation error shown in FIG. 9, according to an embodiment of the inventive concept.

Referring to FIGS. 1 and 10, in step 1, the memory controller 10A reads the first data D1 from the memory cell MC at the first voltage level A. In this case, “1” is read from the memory cells MC having threshold voltages Vth lower than the first voltage level A, and “0” is read from the memory cells MC having threshold voltages Vth higher than the first voltage level A. The first data D1 read in step 1 may be temporarily stored in the page buffer unit 22.

In step 2, the memory controller 10A reads the second data D2 from the memory cell MC n times (n being a natural number equal to or greater than 2) at the second voltage level B, the number of times that “1” is read from among the n times is accumulated. Ideally, “1” is read from the memory cells MC having threshold voltages Vth lower than the second voltage level B, and “0” is read from the memory cells MC having threshold voltages Vth higher than the second voltage level B. The second data D2 read in step 2 may be temporarily stored in the page buffer unit 22.

However, since a read error may occur as described above, “0” may be read at the second voltage level B from the memory cell MC having a threshold voltage Vth between the first and second voltage levels A and B. Accordingly, the read error may be removed by repeatedly performing a read operation n times at the second voltage level B.

In step 3, the page buffer unit 22 performs a logic operation on the first data D1 read at the first voltage level A, and the second data D2 read at the second voltage level B. In an embodiment, the page buffer unit 22 performs an XOR operation on the first and second data D1 and D2.

If the read operation is performed repeatedly in step 2, as described above, the read operation may take a relatively long time. Operation time may be increased due to an additional operation for accumulating results of the read operation performed n times, for example, and thus the efficiency of the read operation may be reduced.

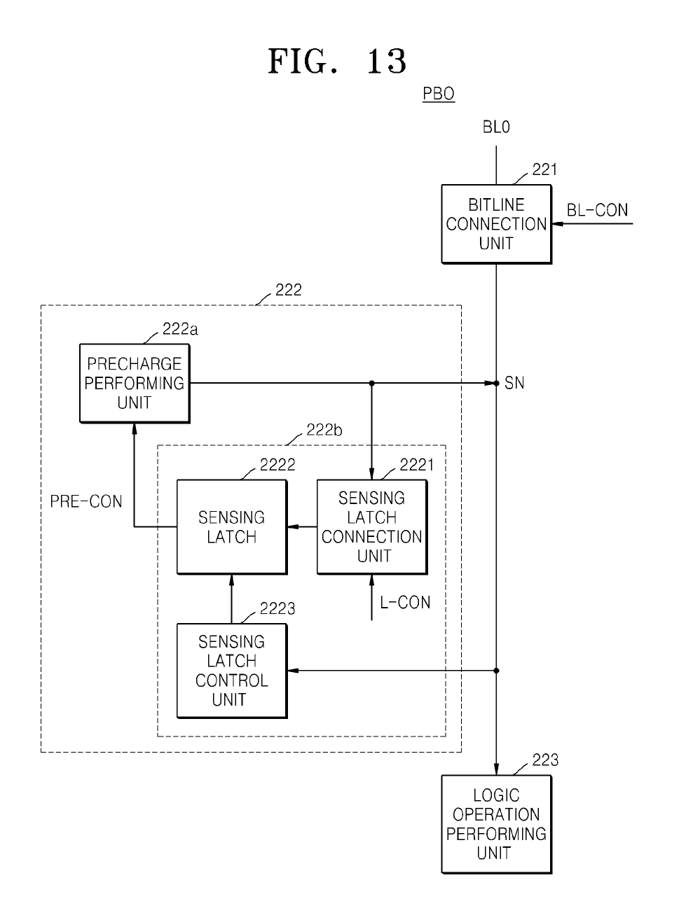

FIG. 11 is a detailed block diagram of the memory device 20A illustrated in FIG. 1, according to an embodiment of the inventive concept.

Referring to FIG. 11, the memory device 20A includes the memory cell array 21 and the page buffer unit 22. The memory cell array 21 includes a page PAG, and the page PAG includes d memory cells MC0 to MCd−1. Although, the memory cell array 21 includes one page PAG in FIG. 11 for purposes of illustration, the memory cell array 21 may also include multiple.

The page buffer unit 22 include multiple page buffers PB0 to PBd−1, and the page buffers PB0 to PBd−1 are respectively connected to the memory cells MC0 to MCd−1 via bitlines BL0 through BLd−1 corresponding to the page buffers PB0 to PBd−1. The page buffers PB0 to PBd−1 temporarily store data to be recorded onto or data read from the memory cell array 21.

In more detail, when a read operation is performed on the memory device 20A, the page buffers PB0 to PBd−1 respectively store data sequentially read from the memory cells MC0 to MCd−1 at different voltage levels. Then, the page buffers PB0 to PBd−1 respectively determine whether to precharge the bitlines BL0 to BLd−1, based on the stored data and a read direction of applying the different voltage levels. After that, the page buffers PB0 to PBd−1 may perform a logic operation on the data. In the current embodiment, the page buffers PB0 to PBd−1 may perform an XOR operation on data read at two adjacent voltage levels from among the different voltage levels.

FIG. 12 is a detailed block diagram of the page buffer PB0 illustrated in FIG. 11, according to an embodiment of the inventive concept.

Referring to FIG. 12, the page buffer PB0 includes a bitline connection unit 221, a precharge unit 222, and a logic operation performing unit 223. Although only the page buffer PB0 is illustrated in FIG. 12 from among the page buffers PB0 to PBd−1 illustrated in FIG. 11, the other page buffers PB1 to PBd−1 may have structures similar to the structure illustrated in FIG. 12.

The bitline connection unit 221 selectively connects the memory cell MC0 included in the memory cell array 21 to a sensing node SN via the bitline BL0. The bitline connection unit 221 may be activated in response to a bitline connection control signal BL_CON provided from the memory controller 10A illustrated in FIG. 1 or the control logic unit 24 illustrated in FIG. 2.

The precharge unit 222 selectively precharges the sensing node SN based on a voltage of the sensing node SN. In more detail, the precharge unit 222 precharges the sensing node SN in an initial state, i.e., when a read operation is started. When a read direction is a direction of applying increasing voltage levels, the precharge unit 222 continuously precharges the sensing node SN when currently read data is in an “off” state, and stops precharging the sensing node SN when the currently read data is in an “on” state. When the read direction is a direction of applying decreasing voltage levels, the precharge unit 222 continuously precharges the sensing node SN when the currently read data is in the “on” state, and stops precharging the sensing node SN when the currently read data is in the “off” state. The precharge unit 222 precharges the sensing node SN in the initial state.

In more detail, the precharge unit 222 includes a precharge performing unit 222a and a precharge control unit 222b. The precharge control unit 222b determines whether to precharge the sensing node SN based on the voltage of the sensing node SN, and thus generates a precharge control signal PRE_CON. The precharge performing unit 222a precharges the sensing node SN based on the precharge control signal PRE_CON.

The logic operation performing unit 223 is connected to the sensing node SN, and performs a logic operation on data sequentially read at different voltage levels. In the current embodiment, the logic operation performing unit 223 performs an XOR operation, for example, on the read data.

FIG. 13 is a detailed block diagram of the precharge control unit in the page buffer PB0 illustrated in FIG. 12, according to an embodiment of the inventive concept.

Referring to FIG. 13, the page buffer PB0 includes the bitline connection unit 221, the precharge unit 222, and the logic operation performing unit 223, and the precharge unit 222 includes the precharge performing unit 222a and the precharge control unit 222b, as discussed above. In the current embodiment, the precharge control unit 222b includes a sensing latch connection unit 2221, a sensing latch 2222, and a sensing latch control unit 2223.

The sensing latch connection unit 2221 selectively transmits a voltage of the sensing node SN to an input terminal of the sensing latch 2222. The sensing latch connection unit 2221 may be activated due to a latch connection control signal L_CON provided from the memory controller 10A illustrated in FIG. 1 or the control logic unit 24 illustrated in FIG. 2, for example.

The sensing latch 2222 latches and transmits the voltage at its input terminal to its output terminal, and provides the voltage at its output terminal to the precharge performing unit 222a as the precharge control signal PRE_CON. In this case, the voltages of the input and output terminals of the sensing latch 2222 are controlled by the sensing latch control unit 2223. The sensing latch control unit 2223 controls the sensing latch 2222 based on the voltage of the sensing node SN and multiple control signals (not shown).

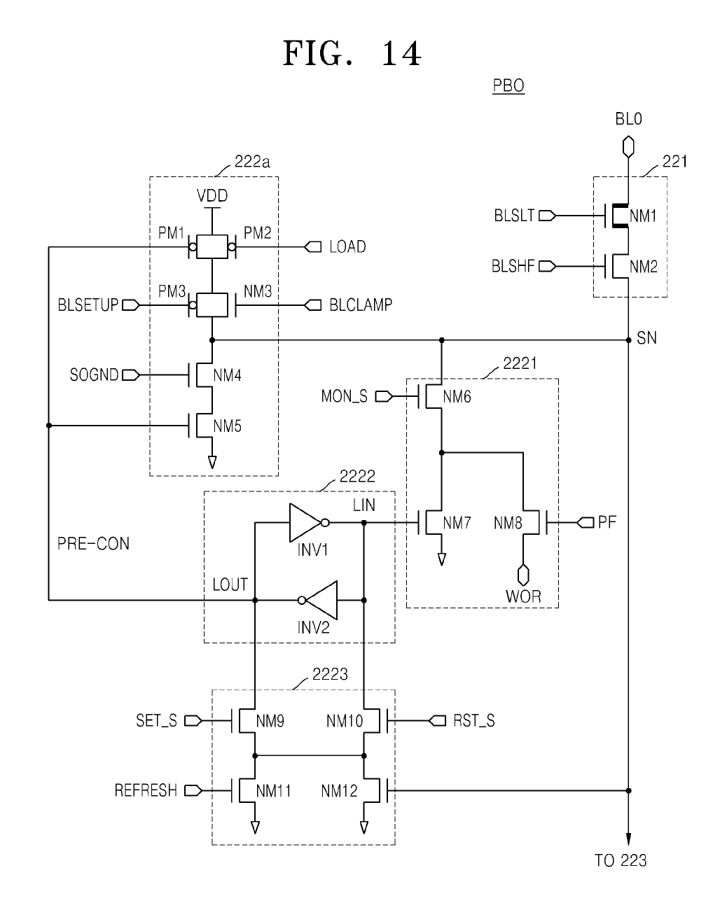

FIG. 14 is a circuit diagram of the page buffer PB0 illustrated in FIG. 13, according to an embodiment of the inventive concept.

Referring to FIG. 14, in the page buffer PB0, the bitline connection unit 221 includes first and second NMOS transistors NM1 and NM2 connected in series. A drain of the first NMOS transistor NM1 may be connected to the bitline BL0, and a source of the second NMOS transistor NM2 may be connected to the sensing node SN. In this case, the first and second NMOS transistors NM1 and NM2 are selectively turned on due to bitline connection control signals BLSLT and BLSHF, respectively. In an embodiment, the first NMOS transistor NM1 may be a high voltage transistor capable of transmitting a high voltage without damaging a device.

The precharge performing unit 222a includes first through third PMOS transistors PM1 to PM3 and third through fifth NMOS transistors NM3 to NM5. The first and second PMOS transistors PM1 and PM2 form a first transmission gate, and the third PMOS transistor PM3 and the third NMOS transistor NM3 may form a second transmission gate. The fourth and fifth NMOS transistors NM4 and NM5 are connected in series. Gates of the first PMOS transistor PM1 and the fifth NMOS transistor NM5 are commonly connected to the output terminal of the sensing latch 2222, i.e., latch output node LOUT.

The sensing latch connection unit 2221 includes sixth through eighth NMOS transistors NM6 to NM8. A gate of the seventh NMOS transistor NM7 is connected to the input terminal of the sensing latch 2222, i.e., latch input node LIN.

The sensing latch 2222 includes first and second inverters INV1 and INV2, and latches and transmits a voltage of the latch input node LIN to the latch output node LOUT. The latch input node LIN is commonly connected to an output terminal of the first inverter INV1 and an input terminal of the second inverter INV2, and the latch output node LOUT is commonly connected to an input terminal of the first inverter INV1 and an output terminal of the second inverter INV2.

The sensing latch control unit 2223 includes ninth through twelfth NMOS transistors NM9 to NM12, and controls the sensing latch 2222 based on a voltage of the sensing node SN and multiple control signals, i.e., a set signal SET_S, a reset signal RST_S, and a refresh signal REFRESH. The ninth NMOS transistor NM9 has a drain connected to the latch output node LOUT, a gate to which the set signal SET_S is applied, and a source commonly connected to a source of the tenth NMOS transistor NM10 and drains of the eleventh NMOS transistor NM11 and the twelfth NMOS transistor NM12. The tenth NMOS transistor NM10 has a drain connected to the latch input node LIN and a gate to which the reset signal RST_S is applied. The eleventh NMOS transistor NM11 has a gate to which the refresh signal REFRESH is applied, and a source connected to a ground terminal. The twelfth NMOS transistor NM12 has a gate connected to the sensing node SN, and a source connected to the ground terminal.

According to the current embodiment, when a voltage of the latch output node LOUT is at a logic “0” level, the bitline BL0 is precharged to a power supply voltage VDD. When the voltage of the latch output node LOUT is at a logic “1” level, the bitline BL0 is not be precharged and is maintained at a ground voltage GND.

In an initial state, i.e., when a read operation of a memory cell is started, the set signal SET_S and the refresh signal REFRESH are activated to the logic “1” level, and thus the ninth and eleventh NMOS transistors NM9 and NM 11 are turned on. Accordingly, the voltage of the latch output node LOUT is the ground voltage GND, and the precharge control signal PRE_CON is at the logic “0” level (SOGND, BLSHF, BLSLT, BLSETUP, and BLCLAMP may be at the logic “1” level). As such, the first through third NMOS transistors NM1 to NM3 and the first PMOS transistor PM1 are turned on, and thus the bitline BL0 is precharged to the power supply voltage VDD.

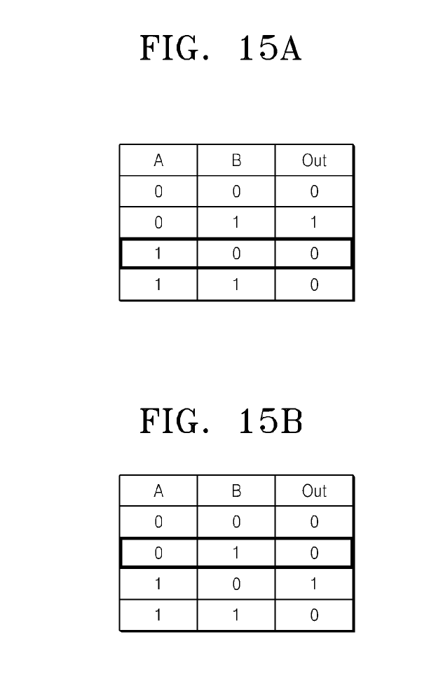

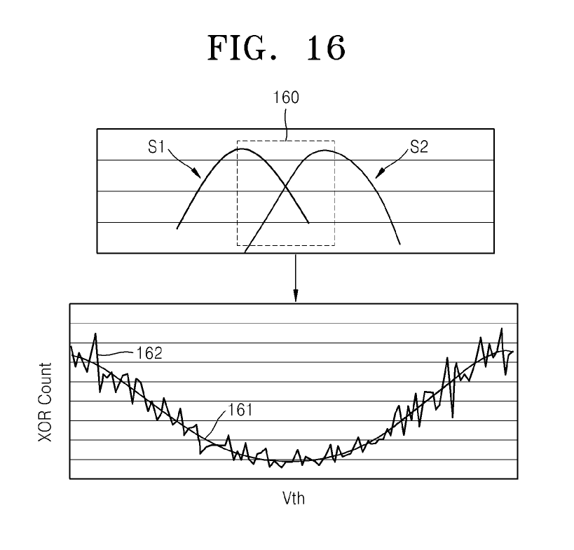

FIG. 15A is a table showing operation results of the page buffer PB0 illustrated in FIGS. 11 to 14 when the read direction is a direction of applying increasing voltage levels.

FIG. 15B is a table showing operation results of the page buffer PB0 illustrated in FIGS. 11 to 14 when the read direction is a direction of applying decreasing voltage levels. Operation of the page buffer PB0 will now be described in detail with reference to FIGS. 11 to 14, 15A, and 15B.

Referring to FIGS. 11 to 14, and 15A, since the voltage levels are increasing, the second voltage level B is higher than the first voltage level A. When the first and second data D1 and D2 respectively read at the first and second voltage levels A and B are “0” and “0”, the precharge control unit 222b generates the precharge control signal PRE_CON at a logic “0” level. Thus, the precharge performing unit 222a continuously precharges the bitline BL0. That is, the page buffer PB0 performs an XOR operation on the read data, i.e., “0” and “0,” and outputs a result of the XOR operation as “0.”

When the first and second data D1 and D2 respectively read at the first and second voltage levels A and B are “0” and “1”, if current data, as “1,” that is, if a memory cell is turned on, since the memory cell may not be turned off again, the precharge control unit 222b generates the precharge control signal PRE_CON at a logic “1” level. Thus, the precharge performing unit 222a stops precharging the bitline BL0. That is, the page buffer PB0 performs an XOR operation on the read data, i.e., “0” and “1,” and outputs a result of the XOR operation as “1.” Accordingly, the read voltage control unit 12 is able to determine that the memory cell exists between the first and second voltage levels A and B.

If the precharging of the bitline BL0 is stopped as described above, a result of reading the memory cell is “0,” and thus it is determined that the memory cell is turned off. Accordingly, data read at subsequent voltage levels will always be “0.” Thus, the page buffer PB0 performs an XOR operation on the read data, i.e., “0” and “0,” and outputs a result of the XOR operation as “0.” As such, the read voltage control unit 12 is able to determine that the memory cell does not exist between subsequent voltage levels.

Thus, according to the current embodiment, the case in which the first and second data D1 and D2 respectively read at the first and second voltage levels A and B are “1” and “0” may be prevented in advance. This prevents an error of reading a memory cell, which has been turned off once, as being turned on, e.g., due to unstable operation of the memory cell, power noise, unstable analog level, or the like.

Referring to FIGS. 11 to 14, and 15B, since the voltage levels are decreasing, the second voltage level B is lower than the first voltage level A. When the first and second data D1 and D2 respectively read at the first and second voltage levels A and B are “1” and “1,” the precharge control unit 222b generates the precharge control signal PRE_CON at a logic “0” level. Thus, the precharge performing unit 222a continuously precharges the bitline BL0. That is, the page buffer PB0 performs an XOR operation on the read data, i.e., “1” and “1,” and outputs a result of the XOR operation as “0.”

When the first and second data D1 and D2 respectively read at the first and second voltage levels A and B are “1” and “0,” if current data, as “0,” that is, if a memory cell is turned off, since the memory cell may not be turned on again, the precharge control unit 222b generate the precharge control signal PRE_CON at a logic “1” level. Thus, the precharge performing unit 222a stops precharging the bitline BL0. That is, the page buffer PB0 performs an XOR operation on the read data, i.e., “1” and “0,” and outputs a result of the XOR operation as “1.” Accordingly, the read voltage control unit 12 is able to determine that the memory cell exists between the first and second voltage levels A and B.

If the precharging of the bitline BL0 is stopped as described above, a result of reading a memory cell is “0,” and thus it is determined that the memory cell is turned off. Accordingly, data read at subsequent voltage levels is always “0,” and thus the page buffer PB0 performs an XOR operation on the read data, i.e., “0” and “0,” and outputs a result of the XOR operation as “0.” As such, the read voltage control unit 12 is able to determine that the memory cell does not exist between subsequent voltage levels.

Thus, according to the current embodiment, a case in which the first and second data D1 and D2 respectively read at the first and second voltage levels A and B are “0” and “1” may be prevented in advance. This prevents an error of reading a memory cell, which has been turned off once, as being turned on, e.g., due to unstable operation of the memory cell, power noise, unstable analog level, or the like.

FIG. 16 is a graph showing results of counting performed by the read voltage control unit 12 illustrated in FIG. 1, according to an embodiment of the inventive concept.

Referring to FIG. 16, the horizontal axis represents the threshold voltages Vth, the vertical axis represents an XOR count, and region 160 represents an overlapping region of the two adjacent distributions S1 and S2. In this case, reference numeral 161 represents an XOR count counted by the read voltage control unit 12 based on results of logic operations performed based on data read by the page buffer unit 22 and a read direction. Reference numeral 162 represents an XOR count counted by the read voltage control unit 12 based on results of logic operations performed based on only the data read by the page buffer unit 22. As illustrated in FIG. 16, according to the current embodiment, the page buffer unit 22 reduces errors by performing logic operations based on the read data and the read direction in comparison to the case in which the logic operations are performed based on only the read data.

The read voltage control unit 12 may count the number of times that “1” is read from among results of the logic operation, e.g., an XOR operation, which are output from the page buffer unit 22. As described above, when a result of the XOR operation performed on first and second data read at two adjacent voltage levels is “1,” it is determined that the memory cell exists in a section between the two adjacent voltage levels. Accordingly, when the number of times that “1” is read is counted from among results of the XOR operation, the number of memory cells in each of multiple sections defined by corresponding multiple voltage levels may be counted. Based on the number of memory cells counted as described above, an optimum voltage level of a read voltage between two adjacent distributions may be determined.

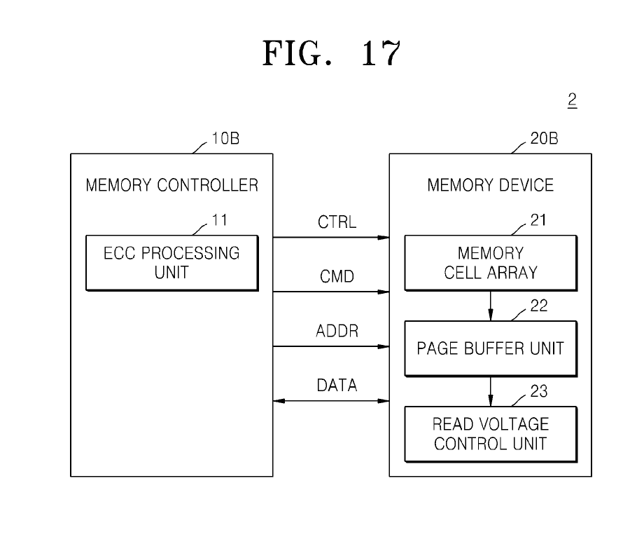

FIG. 17 is a block diagram of a memory system 2, according to another embodiment of the inventive concept.

Referring to FIG. 17, the memory system 2 includes a memory controller 10B and a memory device 20B. The memory controller 10B includes the ECC processing unit 11. The memory device 20B includes the memory cell array 21, the page buffer unit 22, and a read voltage control unit 23. Some of the elements included in the memory system 2 are substantially the same as those included in the memory system 1 illustrated in FIG. 1. Like elements in FIGS. 1 and 17 are denoted by like reference numerals and the descriptions thereof will not be repeated. Differences between the memory systems 1 and 2 are described below.

The read voltage control unit 23 controls a read voltage of memory cells based on results of a logic operation, which are output from the page buffer unit 22. In more detail, the read voltage control unit 23 counts the number of memory cells in each of multiple sections defined by different voltage levels based on the results of the logic operation, and determines an optimum voltage level of the read voltage based on the result of the counting.

According to the current embodiment, the read voltage control unit 23 is included in the memory device 20B. As such, the results of the logic operation, which are output from the page buffer unit 22, are not provided to the memory controller 10B.

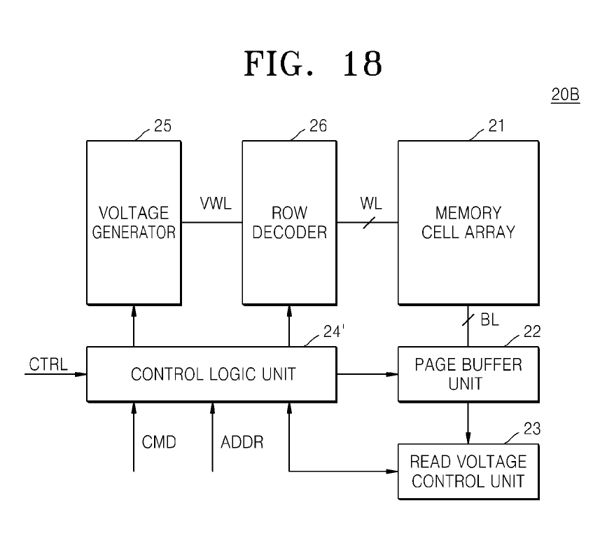

FIG. 18 is a detailed block diagram of the memory device 20B included in the memory system 2 illustrated in FIG. 17, according to an embodiment of the inventive concept.

Referring to FIG. 18, the memory device 20B includes the memory cell array 21, the page buffer unit 22, the read voltage control unit 23, a control logic unit 24′, the voltage generator 25, and the row decoder 26. Some of the elements included in the memory device 20B are substantially the same as those included in the memory device 20A illustrated in FIG. 2. Like elements in FIGS. 2 and 18 are denoted by like reference numerals and the descriptions thereof will not be repeated. Differences between the memory devices 20A and 20B are described below.

The control logic unit 24′ outputs various control signals for writing or reading data into or from the memory cell array 21 based on the command signals CMD, the address signals ADDR, and the control signals CTRL received from the memory controller 10B. In this case, the various control signals output from the control logic unit 24′ are transmitted to the voltage generator 25, the row decoder 26, the page buffer unit 22, and the read voltage control unit 23. The read voltage control unit 23 is connected to the page buffer unit 22, and controls a read voltage of memory cells based on results of a logic operation, which are output from the page buffer unit 22.

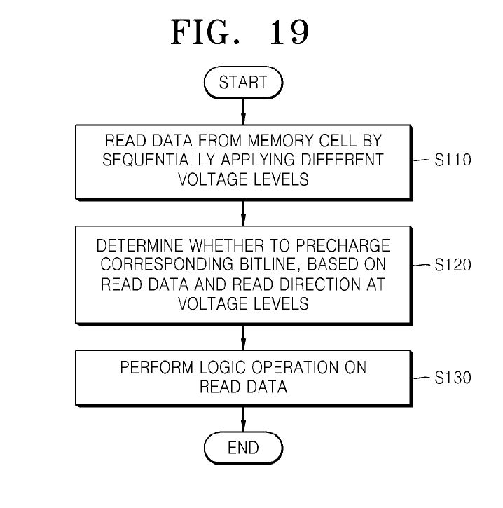

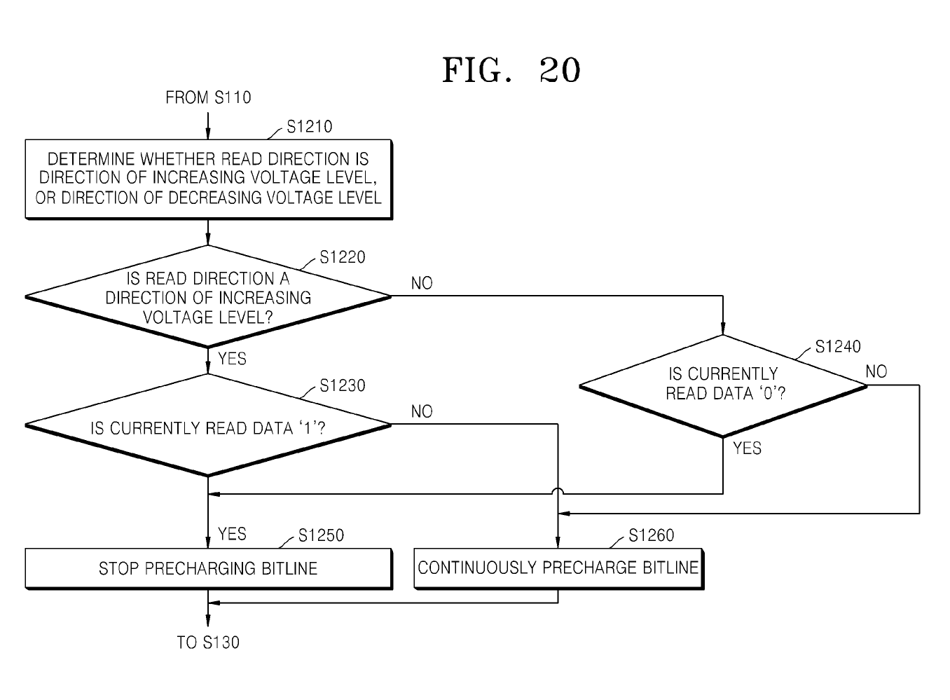

FIG. 19 is a flowchart of a method of controlling a read voltage of a memory device, according to an embodiment of the inventive concept.

Referring to FIG. 19, according to the current embodiment, a method is provided for controlling a read voltage for reading data stored in a memory cell array included in a memory device. The descriptions provided above in relation to the memory devices 20A and 20B and the memory systems 1 and 2 illustrated in FIGS. 1 through 18 are also applied to the method according to the current embodiment.

In step S110, data is read from a memory cell by sequentially applying different voltage levels. For example, a memory controller may provide information regarding the voltage levels to the memory device as a control signal, and a read operation of the memory cell may be performed by applying the voltage levels to a wordline connected to a memory cell array included in the memory device. In this case, the read data may be temporarily stored in a page buffer unit included in the memory device.

In step S120, it is determined whether to precharge a corresponding bitline based on the read data and a read direction of applying the different voltage levels. For example, the page buffer unit included in the memory device may determine whether to precharge a corresponding bitline, based on the data temporarily stored in the page buffer unit, and the read direction.

In step S130, a logic operation is performed on the read data. For example, the page buffer unit included in the memory device may perform an XOR operation on the data read at adjacent voltage levels.

FIG. 20 is a detailed flowchart of the step S120 of determining whether to perform precharge in the method illustrated in FIG. 19, according to an embodiment of the inventive concept.

Referring to FIG. 20, in step S1210, it is determined whether a read direction of applying two adjacent voltage levels is a direction of increasing voltage levels or a direction of decreasing voltage levels. A direction of increasing voltage levels refers to a case in which data is read at a first voltage level and then data is read at a second voltage level higher than the first voltage level. A direction of decreasing voltage levels refers to a case in which data is read at the second voltage level and then data is read at the first voltage level lower than the second voltage level.

In step S1220, when it is determined that the read direction is a direction of applying increasing voltage levels, the method proceeds to step S1230. Otherwise, when it is determined that the read direction is a direction of applying decreasing voltage levels, the method proceeds to step S1240.

In step S1230, it is determined whether the currently read data is “1.” When the currently read data is “1,” that is, the memory cell is turned on, the method proceeds to step S1250. Otherwise, the method proceeds to step S1260. In step S1240, it is determined whether the currently read data is “0.” When the currently read data is “0,” that is, the memory cell is turned off, the method proceeds to step S1250. Otherwise, the method proceeds to step S1260. In step S1250, the precharging of the bitline is stopped. In step S1260, the bitline continues to be precharged.

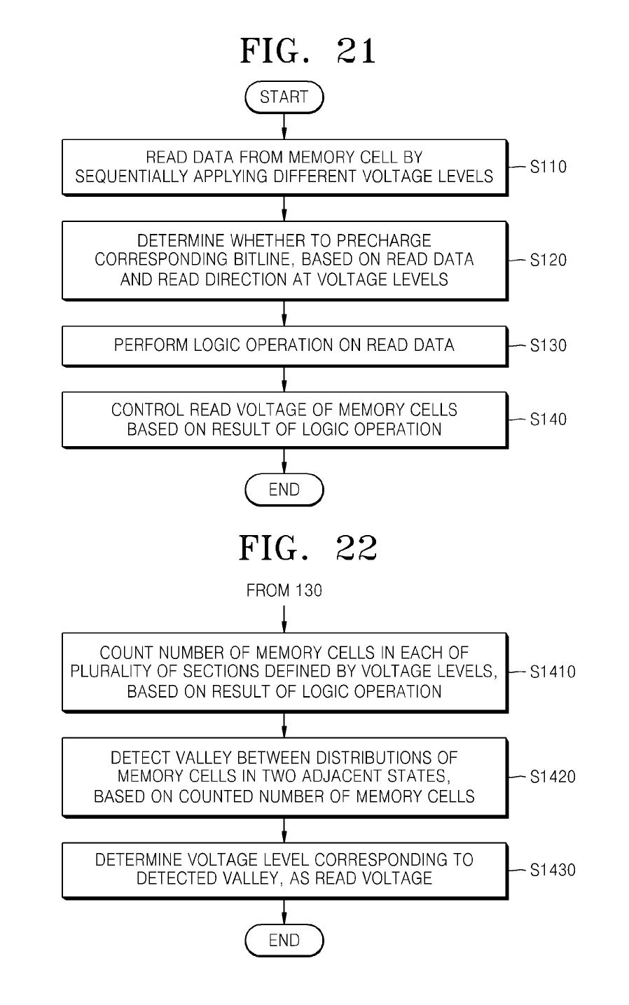

FIG. 21 is a flowchart of a method of controlling a read voltage of a memory device, according to another embodiment of the inventive concept.

Referring to FIG. 21, according to the current embodiment, a method is provided for controlling a read voltage for reading data stored in a memory cell array included in a memory device. The descriptions provided above in relation to the memory devices 20A and 20B and the memory systems 1 and 2 illustrated in FIGS. 1 through 18 are also applied to the method according to the current embodiment.

In step S110, data is read from a memory cell by sequentially applying different voltage levels. For example, a memory controller may provide information regarding the voltage levels to the memory device as a control signal, and a read operation of the memory cell may be performed by applying the voltage levels to a wordline connected to a memory cell array included in the memory device. In this case, the read data may be temporarily stored in a page buffer unit included in the memory device.

In step S120, it is determined whether to precharge a corresponding bitline, based on the read data and a read direction of applying the different voltage levels. For example, the page buffer unit included in the memory device may determine whether to precharge a corresponding bitline, based on the data temporarily stored in the page buffer unit, and the read direction.

In step S130, a logic operation is performed on the read data. For example, the page buffer unit included in the memory device may perform an XOR operation on the data read at adjacent voltage levels.

In step S140, a read voltage of memory cells is controlled based on results of the logic operation. In one embodiment, a read voltage control unit may be included in a memory controller and, in this case, step S140 may be performed by the memory controller. In another embodiment, the read voltage control unit may be included in the memory device and, in this case, step S140 may be performed by the memory device.

FIG. 22 is a detailed flowchart of the step S140 of controlling the read voltage of the memory cells in the method illustrated in FIG. 21, according to an embodiment of the inventive concept.

Referring to FIG. 22, in step S1410, the number of memory cells in each of multiple sections defined by the voltage levels is counted based on results of the logic operation. For example, the read voltage control unit included in the memory controller or the memory device may include a counter, which determines an XOR count in each section based on the results of the logic operation. Thus, the number of memory cells in each section may be counted.

In step S1420, a valley is detected between distributions of memory cells in two adjacent states, based on the counted numbers of memory cells. For example, the read voltage control unit may detect that the valley occurs where the number of memory cells in the sections decreases and then increases.

In step S1430, a voltage level corresponding to the detected valley is determined as the read voltage. For example, the read voltage control unit may determine the voltage level corresponding to the detected valley as an optimum voltage level of the read voltage. As such, the optimum voltage level of the read voltage may be accurately determined by performing a simple operation.

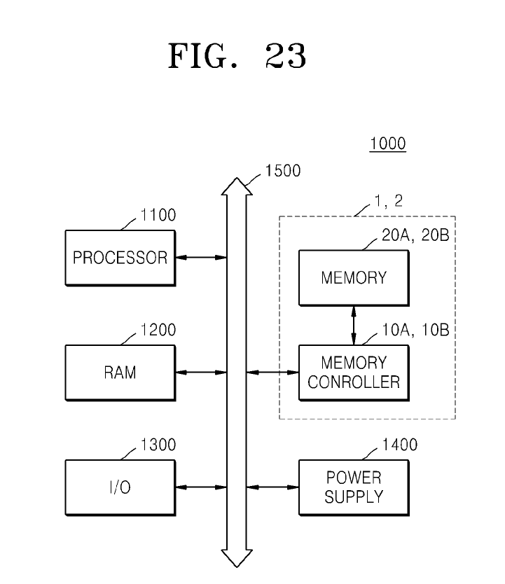

FIG. 23 is a block diagram of a computing system 1000 including the memory system 1 or 2 illustrated in FIG. 1 or 17, according to embodiments of the inventive concept.

Referring to FIG. 23, the computing system 1000 includes a processor 1100, a random access memory (RAM) 1200, an I/O device 1300, a power supply 1400, and the memory system 1 or 2. Although not shown in FIG. 23, the computing system 1000 may further include ports capable of communicating with a video card, a sound card, a memory card, a universal serial bus (USB) device, and other electronic devices. The computing system 1000 may be implemented as a personal computer (PC) or a portable electronic device such as a laptop computer, a mobile phone, a personal digital assistant (PDA), or a camera.

The processor 1100 may perform certain calculations or tasks. According to an embodiment, the processor 1100 may be a micro-processor or a central processing unit (CPU). The processor 1100 may communicate with the RAM 1200, the I/O device 1300, and the memory system 1 or 2 via a bus 1500 such as an address bus, a control bus, or a data bus. According to an embodiment, the processor 1100 may be connected to an extension bus such as a peripheral component interconnection (PCI) bus.

The RAM 1200 may store data required to operate the computing system 1000. For example, the RAM 1200 may be implemented as dynamic random access memory (DRAM), mobile DRAM, static random access memory (SRAM), phase-change random access memory (PRAM), ferroelectric random access memory (FRAM), resistive random access memory (RRAM), and/or magnetic random access memory (MRAM).

The I/O device 1300 may include an input unit such as a keyboard, a keypad, or a mouse, and an output unit such as a printer or a display. The power supply 1400 may supply operation voltages required to operate the computing system 1000.

While the inventive concept has been described with reference to illustrative embodiments, it will be apparent to those skilled in the art that various changes and modifications may be made without departing from the spirit and scope of the present inventive concept. Therefore, it should be understood that the above embodiments are not limiting, but illustrative.

What is claimed is:

1. A memory device comprising:
a memory cell array comprising a plurality of memory cells; and
a page buffer unit for performing a logic operation on data sequentially read from the plurality of memory cells at different voltage levels, based on the read data and a read direction of applying the different voltage levels.

2. The memory device of claim 1, wherein the plurality of memory cells are disposed in regions where a plurality of wordlines and a plurality of bitlines cross each other, and
wherein the page buffer unit comprises a plurality of page buffers connected to the plurality of bitlines, respectively.

3. The memory device of claim 2, wherein each of the plurality of page buffers determines whether to precharge a corresponding bitline based on the data sequentially read at the different voltage levels from a memory cell connected to the corresponding bitline from among the plurality of memory cells and the read direction of applying the different voltage levels.

4. The memory device of claim 3, wherein, when the read direction is a direction of applying increasing voltage levels, each of the plurality of page buffers continuously precharges the corresponding bitline when currently read data has a first logic level, and stops precharging the corresponding bitline when the currently read data has a second logic level, and
wherein the first logic level corresponds to the memory cell being turned off, and the second logic level corresponds to the memory cell being turned on.

5. The memory device of claim 3, wherein, when the read direction is a direction of applying decreasing voltage levels, each of the plurality of page buffers continuously precharges the corresponding bitline when currently read data has a second logic level, and stops precharging the corresponding bitline when the currently read data has a first logic level, and
wherein the first logic level corresponds to the memory cell being turned off, and the second logic level corresponds to the memory cell being turned on.

6. The memory device of claim 3, wherein each of the plurality of page buffers performs an XOR operation on the read data.

7. The memory device of claim 2, wherein each of the plurality of page buffers comprises:
a bitline connection unit for connecting a corresponding bitline to a sensing node;
a precharge unit for selectively precharging the sensing node based on a voltage of the sensing node; and
a logic operation performing unit connected to the sensing node for performing the logic operation on the data sequentially read at the different voltage levels.

8. The memory device of claim 7, wherein, when the read direction is a direction of applying increasing voltage levels, the precharge unit continuously precharges the sensing node when currently read data has a first logic level, and stops precharging the sensing node when the currently read data has a second logic level, and
wherein the first logic level corresponds to a case when the memory cell is turned off, and the second logic level corresponds to a case when the memory cell is turned on.

9. The memory device of claim 7, wherein, when the read direction is a direction of applying decreasing voltage levels, the precharge unit continuously precharges the sensing node when the currently read data has a second logic level, and stops precharging the sensing node when the currently read data has the first logic level, and
wherein the first logic level corresponds to a case when the memory cell is turned off, and the second logic level corresponds to a case when the memory cell is turned on.

10. The memory device of claim 7, wherein the precharge unit precharges the sensing node in an initial state.

11. The memory device of claim 7, wherein the precharge unit comprises:
a precharge control unit for determining whether to precharge the sensing node, based on the voltage of the sensing node, and generating a precharge control signal; and
a precharge performing unit for precharging the sensing node based on the precharge control signal.

12. The memory device of claim 11, wherein the precharge control unit comprises:
a sensing latch connection unit for transmitting the voltage of the sensing node to a latch input node;
a sensing latch for latching and transmitting a voltage of the latch input node to a latch output node, and providing a voltage of the latch output node to the precharge performing unit as the precharge control signal; and
a sensing latch control unit for controlling the sensing latch based on a plurality of control signals.

13. The memory device of claim 1, further comprising:
a counter for counting a number of memory cells in each of a plurality of sections defined by the different voltage levels based on results of the logic operation.

14. The memory device of claim 1, further comprising:
a read voltage control unit for counting a number of memory cells in each of a plurality of sections defined by the different voltage levels, based on results of the logic operation, and for controlling a read voltage of the memory cells based on a result of the counting.

15. A memory system comprising:
a memory device; and
a memory controller for controlling the memory device,
wherein the memory device comprises:
a memory cell array comprising a plurality of memory cells; and
a page buffer unit for performing a logic operation on data sequentially read from the plurality of memory cells at different voltage levels, based on the read data and a read direction of applying the different voltage levels.

16. The memory system of claim 15, wherein the memory controller comprises a read voltage control unit for counting a number of memory cells in each of a plurality of sections defined by the different voltage levels, based on results of the logic operation, and for controlling a read voltage of the memory cells based on a result of the counting.

17. A method of controlling a read voltage for reading data stored in a memory cell array comprising a plurality of memory cells, the method comprising:
reading data from the plurality of memory cells by sequentially applying different voltage levels to each of the plurality of memory cells;
temporarily storing the read data in a plurality of page buffers corresponding to a plurality of bitlines connected to the plurality of memory cells; and
determining whether to precharge the bitlines based on the read data temporarily stored in the corresponding plurality of page buffers and a read direction of applying the different voltage levels.

18. The method of claim 17, further comprising:
performing a logic operation in each of the plurality of page buffers on the data read at adjacent voltage levels; and
determining an optimum voltage level of a read voltage of the plurality of memory cells based on results of the logic operation.

19. The method of claim 18, wherein determining the optimum voltage level of the read voltage comprises:
counting a number of memory cells in each of multiple sections defined by the voltage levels based on results of the logic operation;
detecting a valley between distributions of memory cells in two adjacent states, based on the counted numbers of memory cells; and
determining a voltage level corresponding to the detected valley as the optimum voltage level of the read voltage.

20. The method of claim 18, wherein the logic operation comprises an XOR operation.
